(19) United States
(12) Patent Application Publication
(10) Pub. No.: US 2026/0319031 A1
(43) Pub. Date: Oct. 15, 2026

(54) MAGNETIC SENSOR

(71) Applicant: TDK Corporation, Tokyo (JP)

(72) Inventor: Hidekazu KOJIMA, Tokyo (JP)

(73) Assignee: TDK Corporation, Tokyo (JP)

(21) Appl. No.: 19/639,340

(22) Filed: Apr. 6, 2026

(30) Foreign Application Priority Data
Apr. 11, 2025 (JP) 2025-065559

(51) Int. Cl. G01R 33/09

(52) U.S. Cl. CPC G01R 33/098; G01R 33/093

(57) ABSTRACT

A magnetic sensor includes an MR element arranged on an inclined surface. The MR element includes a bottom surface, a first end portion located at one end of the MR element in a short direction, a second end portion located at the other end thereof in the short direction, and a third end portion located at one end of the MR element in a longitudinal direction, and a fourth end portion located at the other end thereof in the longitudinal direction. The first end portion is inclined at a first angle with respect to the bottom surface. The second end portion is inclined at a second angle with respect to the bottom surface. The third end portion is inclined at a third angle with respect to the bottom surface. At least one of the first angle and the second angle is equal to or smaller than the third angle.

### CROSS-REFERENCE TO RELATED APPLICATION

This application claims the benefit of Japanese Priority Patent Application No. 2025-065559 filed on Apr. 11, 2025, the entire contents of which are incorporated herein by reference.

### BACKGROUND

The disclosure relates to a magnetic sensor including a magnetic detection element arranged on an inclined surface.

In recent years, magnetic sensors including magnetic detection elements have been used in various applications. As a magnetic detection element, a spin-valve magnetoresistive element has been known. The spin-valve magnetoresistive element includes a magnetization pinned layer in which a magnetization direction is fixed, a free layer in which a magnetization direction is variable in accordance with a direction of an applied magnetic field, and a gap layer arranged between the magnetization pinned layer and the free layer. In many cases, a spin-valve magnetoresistive element provided on a substrate is configured to have sensitivity to a magnetic field in a direction parallel to a surface of the substrate. Accordingly, such a magnetoresistive element is suitable for detecting a magnetic field whose direction varies within a plane parallel to the surface of the substrate.

Meanwhile, a system including a magnetic sensor may be intended to detect a magnetic field including a component in a direction perpendicular to the surface of a substrate by using a magnetic detection element provided on the substrate. In this case, by arranging the magnetic detection element on an inclined surface formed on the substrate, it is possible to detect a magnetic field including a component in a direction perpendicular to the surface of the substrate. For example, Japanese Patent Application Laid-Open No. 2006-194733 discloses a magnetic sensor including a giant magnetoresistive element provided on an inclined surface of a ridge portion formed on a substrate, the magnetic sensor including a giant magnetoresistive element having a sensing axis in a direction parallel to the inclined surface, in other words, a direction obliquely upward from the substrate.

When a magnetic detection element is formed on an inclined surface, as in the magnetic sensor disclosed in Japanese Patent Application Laid-Open No. 2006-194733, a side surface of the magnetic detection element is inclined with respect to the inclined surface. In general, a shape of the magnetic detection element has a correspondence with hysteresis characteristics and sensitivity of the magnetic detection element.

### SUMMARY

A magnetic sensor according to one embodiment of the disclosure includes a substrate that includes a reference plane, a support member that is arranged on the substrate, and includes an inclined surface inclined with respect to the reference plane, and a magnetic detection element that is arranged on the inclined surface, and has a long shape in one direction. The magnetic detection element includes a bottom surface facing the inclined surface, a top surface on a side opposite to the bottom surface, a first end portion located at one end of the magnetic detection element in a short direction, a second end portion located at the other end of the magnetic detection element in the short direction, a third end portion located at one end of the magnetic detection element in a longitudinal direction, and a fourth end portion located at the other end of the magnetic detection element in the longitudinal direction. The first end portion is inclined at a first angle with respect to the bottom surface in a first cross section perpendicular to the longitudinal direction. The second end portion is inclined at a second angle with respect to the bottom surface in the first cross section. The third end portion is inclined at a third angle with respect to the bottom surface in a second cross section intersecting with the short direction. At least one of the first angle and the second angle is equal to or smaller than the third angle.

Objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the disclosure.

FIG. 1 is a perspective view showing a magnetic sensor according to an example embodiment of the disclosure.

FIG. 2 is a functional block showing a configuration of a magnetic sensor device including the magnetic sensor according to the embodiment of the disclosure.

FIG. 3 is a circuit diagram showing a configuration circuit of a first detection circuit in the example embodiment of the disclosure.

FIG. 4 is a circuit diagram showing a configuration circuit of a second detection circuit in the example embodiment of the disclosure.

FIG. 5 is a plan view showing a part of the magnetic sensor according to the embodiment of the disclosure.

FIG. 6 is a cross-sectional view showing a part of the magnetic sensor according to the embodiment of the disclosure.

FIG. 7 is a side view of a magnetoresistive element in the example embodiment of the disclosure.

FIG. 8 is a plan view showing a shape of the magnetoresistive element in the example embodiment of the disclosure.

FIG. 9 is a cross-sectional view showing a part of the magnetic sensor according to the embodiment of the disclosure.

FIG. 10 is a cross-sectional view showing a part of the magnetic sensor according to the embodiment of the disclosure.

FIG. 11 is a cross-sectional view showing a part of the magnetic sensor according to the embodiment of the disclosure.

FIG. 12 is a plan view showing a first modification example of the magnetoresistive element in the example embodiment of the disclosure.

FIG. 13 is a plan view showing a second modification example of the magnetoresistive element in the example embodiment of the disclosure.

### DETAILED DESCRIPTION

An object of the disclosure is to provide a magnetic sensor including a magnetic detection element including a plurality of end portions arranged on an inclined surface, the magnetic sensor being capable of achieving desired characteristics.

In the following, some example embodiments and modification examples of the disclosure will be described in detail with reference to the accompanying drawings. Note that the following description is directed to illustrative examples of the disclosure and not to be construed as limiting the disclosure. Factors including, without limitation, numerical values, shapes, materials, components, positions of the components, and how the components are coupled to each other are illustrative only and not to be construed as limiting the disclosure. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

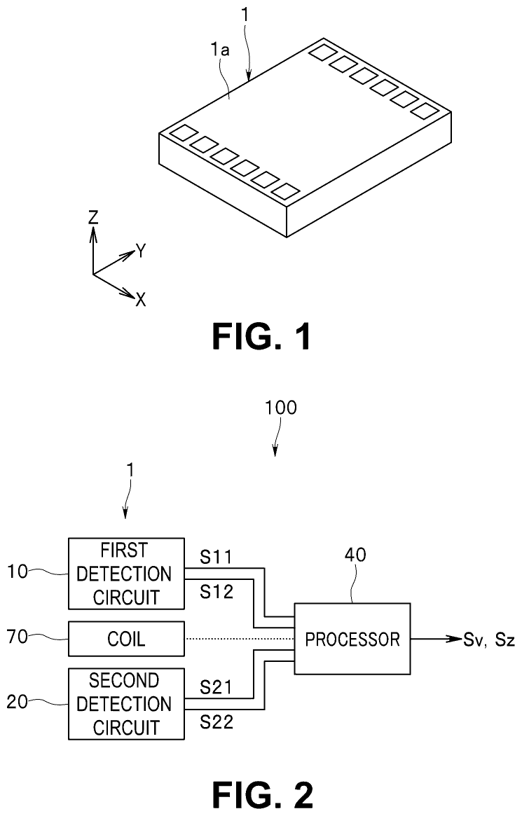

First, with reference to FIG. 1 and FIG. 2, a configuration of a magnetic sensor according to an example embodiment of the disclosure is described. FIG. 1 is a perspective view showing the magnetic sensor according to the example embodiment. FIG. 2 is a functional block diagram showing a configuration of a magnetic sensor device including the magnetic sensor according to the example embodiment.

As shown in FIG. 1, a magnetic sensor 1 may be in the form of a chip having a rectangular parallelepiped shape. The magnetic sensor 1 includes a top surface 1a and a bottom surface that are located opposite to each other, and also includes four side surfaces that connect the top surface 1a to the bottom surface. The magnetic sensor 1 also includes a plurality of electrode pads arranged on the top surface 1a.

Now, with reference to FIG. 1, a reference coordinate system in the example embodiment is described. The reference coordinate system is an orthogonal coordinate system that is set with reference to the magnetic sensor 1 and defined by three axes. An X direction, a Y direction, and a Z direction are defined in the reference coordinate system. The X direction, the Y direction, and the Z direction are orthogonal to each other. In particular, in the example embodiment, a direction that is perpendicular to the top surface 1a of the magnetic sensor 1, and is oriented from the bottom surface to the top surface 1a of the magnetic sensor 1 is defined as the Z direction. The opposite directions to the X, Y, and Z directions will be expressed as −X, −Y, and −Z directions, respectively. The three axes defining the reference coordinate system are an axis parallel to the X direction, an axis parallel to the Y direction, and an axis parallel to the Z direction.

Hereinafter, the term “above” refers to positions located forward of a reference position in the Z direction, and “below” refers to positions opposite from the “above” positions with respect to the reference position. For each component of the magnetic sensor 1, the term “top surface” refers to a surface of the component located at the end thereof in the Z direction, and the term “bottom surface” refers to a surface of the component located at the end thereof in the −Z direction. The expression “when viewed in a specific direction (for example, the Z direction)” means that an object is viewed from a position away in the specific direction or in one direction parallel to the specific direction. Further, for each component of the magnetic sensor 1, a shape in plan view in the Z direction is also referred to as a “planar shape”.

As shown in FIG. 2, the magnetic sensor 1 includes a first detection circuit 10 and a second detection circuit 20. Each of the first and second detection circuits 10 and 20 includes a plurality of magnetic detection elements, and is configured to detect a target magnetic field to generate at least one detection signal. In particular, in the example embodiment, the plurality of magnetic detection elements are a plurality of magnetoresistive elements. Hereinafter, the magnetoresistive element is referred to as an MR element.

A plurality of detection signals generated by the first and second detection circuits 10 and 20 are processed by a processor 40. The magnetic sensor 1 and the processor 40 constitute a magnetic sensor device 100. The processor 40 is configured to, by processing the plurality of detection signals generated by the first and second detection circuits 10 and 20, generate a first detection value and a second detection value respectively having correspondences with components of a magnetic field in two different directions at a specific reference position. In particular, in the example embodiment, the foregoing two different directions are a direction parallel to an XY plane and a direction parallel to the Z direction. For example, the processor 40 is configured by an application-specific integrated circuit (ASIC).

The processor 40 may be included in a support that supports the magnetic sensor 1, for example. The support includes a plurality of electrode pads. The first and second detection circuits 10 and 20 may be connected to the processor 40 via the plurality of electrode pads of the magnetic sensor 1, the plurality of electrode pads of the support, and a plurality of bonding wires, for example. In a case where the plurality of electrode pads of the magnetic sensor 1 are provided on the top surface 1a of the magnetic sensor 1, the magnetic sensor 1 may be mounted on the top surface of the support in such a posture that the bottom surface of the magnetic sensor 1 faces the top surface of the support.

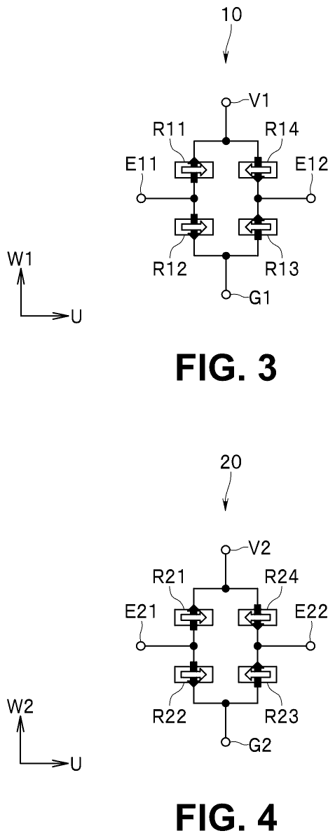

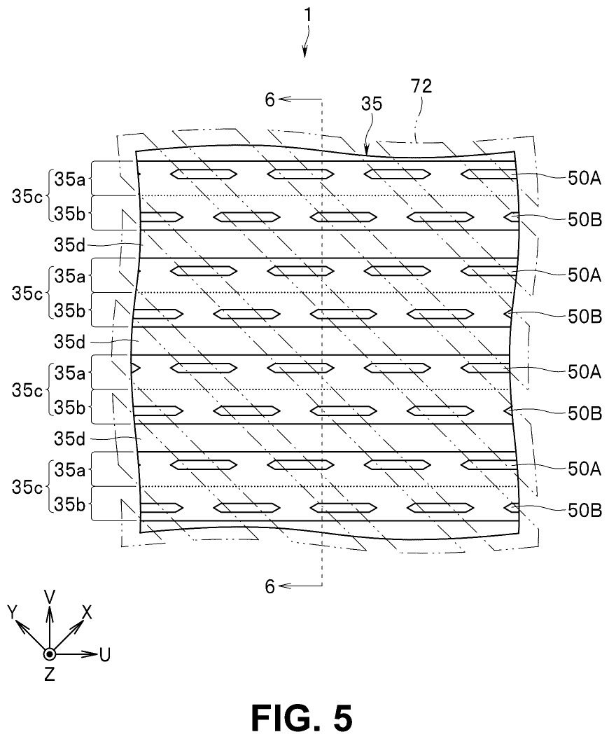

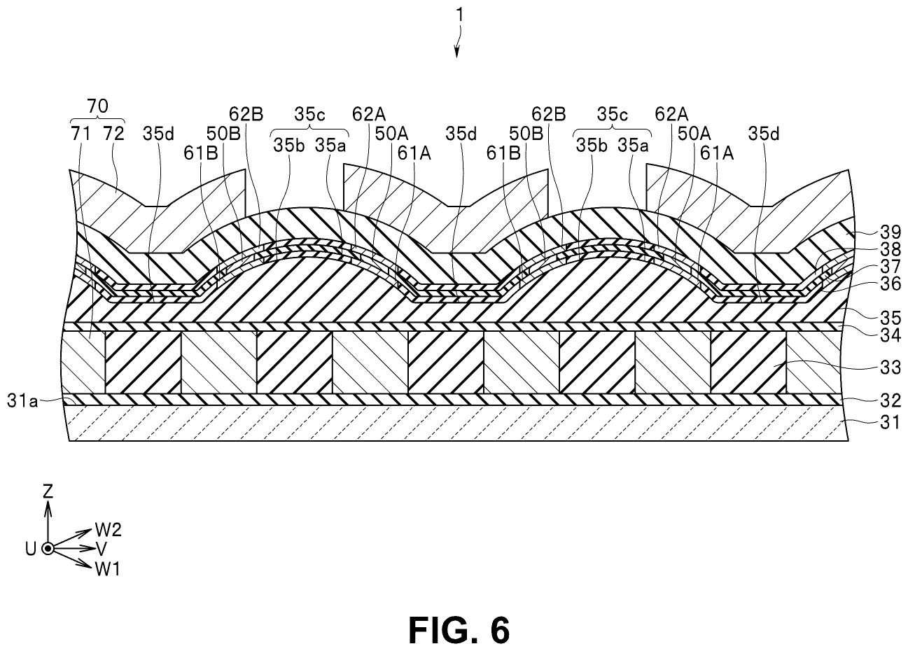

Next, with reference to FIG. 3, FIG. 4, FIG. 5, and FIG. 6, the first and second detection circuits 10 and 20 are described. FIG. 3 is a circuit diagram showing a circuit configuration of the first detection circuit 10. FIG. 4 is a circuit diagram showing a circuit configuration of the second detection circuit 20. FIG. 5 is a plan view showing a part of the magnetic sensor 1. FIG. 6 is a cross-sectional view showing a part of the magnetic sensor 1.

Here, as shown in FIG. 5, a U direction and a V direction are defined as follows. The U direction is a direction rotated from the X direction to the −Y direction. The V direction is a direction rotated from the Y direction to the X direction. In particular, in the example embodiment, the U direction is set to a direction rotated from the X direction to the −Y direction by α, and the V direction is set to a direction rotated from the Y direction to the X direction by α. Note that α is an angle greater than 0 degrees and smaller than 90 degrees. In an example, α is 45 degrees. A −U direction refers to a direction opposite to the U direction, and a −V direction refers to a direction opposite to the V direction.

As shown in FIG. 6, a W1 direction and a W2 direction are defined as follows. The W1 direction is a direction rotated from the V direction to the −Z direction. The W2 direction is a direction rotated from the V direction to the Z direction. In particular, in the example embodiment, the W1 direction is set to a direction rotated from the V direction to the −Z direction by β, and the W2 direction is set to a direction rotated from the V direction to the Z direction by β. Note that β is an angle greater than 0 degrees and smaller than 90 degrees. A −W1 direction refers to a direction opposite to the W1 direction, and a −W2 direction refers to a direction opposite to the W2 direction. The W1 direction and W2 direction both are orthogonal to the U direction.

The first detection circuit 10 is configured to detect a component of the target magnetic field in a direction parallel to the W1 direction and generate at least one first detection signal which has a correspondence with the component. The second detection circuit 20 is configured to detect a component of the target magnetic field in a direction parallel to the W2 direction and generate at least one second detection signal which has a correspondence with the component.

As shown in FIG. 3, the first detection circuit 10 includes a power supply end V1, a ground end G1, signal output ends E11 and E12, and resistor sections R11, R12, R13, and R14. The plurality of MR elements of the first detection circuit 10 constitute the resistor sections R11, R12, R13, and R14.

The resistor section R11 is provided between the power supply end V1 and the signal output end E11. The resistor section R12 is provided between the signal output end E11 and the ground end G1. The resistor section R13 is provided between the signal output end E12 and the ground end G1. The resistor section R14 is provided between the power supply end V1 and the signal output end E12.

As shown in FIG. 4, the second detection circuit 20 includes a power supply end V2, a ground end G2, signal output ends E21 and E22, and resistor sections R21, R22, R23, and R24. The plurality of MR elements of the second detection circuit 20 constitute the resistor sections R21, R22, R23, and R24.

The resistor section R21 is provided between the power supply end V2 and the signal output end E21. The resistor section R22 is provided between the signal output end E21 and the ground end G2. The resistor section R23 is provided between the signal output end E22 and the ground end G2. The resistor section R24 is provided between the power supply end V2 and the signal output end E22.

A voltage or a current of a predetermined magnitude is applied to each of the power supply ends V1 and V2. Each of the ground ends G1 and G2 is connected to the ground.

Hereinafter, the plurality of MR elements of the first detection circuit 10 are referred to as a plurality of first MR elements 50A, and the plurality of MR elements of the second detection circuit 20 are referred to as a plurality of second MR elements 50B. The first and second detection circuits 10 and 20 are the components of the magnetic sensor 1, and hence it can also be understood that the magnetic sensor 1 includes the plurality of first MR elements 50A and the plurality of second MR elements 50B. Any given MR element is denoted by the reference numeral 50.

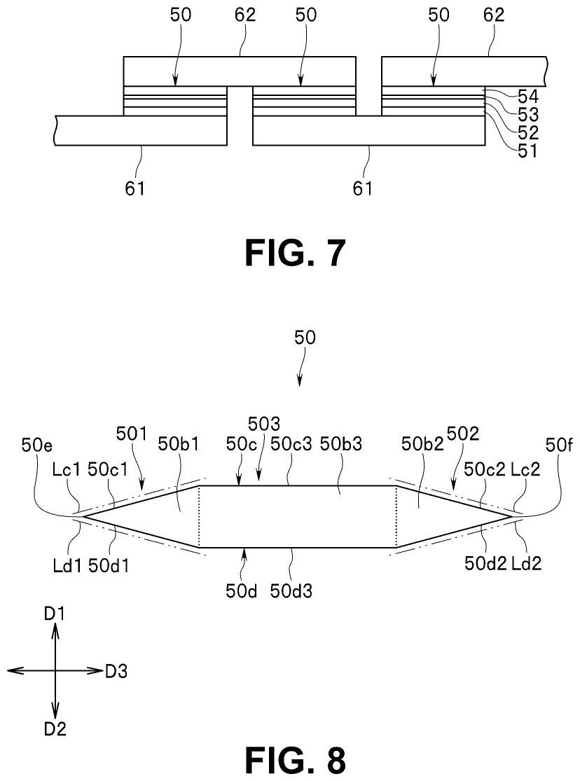

FIG. 7 is a side view showing the MR element 50. The MR element 50 is a spin-valve MR element including a plurality of magnetic layers. The MR element 50 includes a magnetization pinned layer 52 in which a magnetization direction is fixed, a free layer 54 in which a magnetization direction is variable in accordance with a direction of a target magnetic field, and a gap layer 53 arranged between the magnetization pinned layer 52 and the free layer 54. The MR element 50 may be a tunneling magnetoresistive (TMR) element or a giant magnetoresistive (GMR) element. In the TMR element, the gap layer 53 is a tunnel barrier layer. In the GMR element, the gap layer 53 is a nonmagnetic conductive layer.

In the MR element 50, the resistance value varies in accordance with an angle formed by the magnetization direction in the free layer 54 with respect to the magnetization direction in the magnetization pinned layer 52. When the angle is 0 degrees, the resistance value reaches a minimum value. When the angle is 180 degrees, the resistance value reaches a maximum value. In each of the MR elements 50, the free layer 54 has a shape anisotropy that sets the direction of the magnetization easy axis to be orthogonal to the magnetization direction of the magnetization pinned layer 52. As a method of setting the magnetization easy axis in a predetermined direction in the free layer 54, a magnet configured to apply a bias magnetic field to the free layer 54 can be used.

The MR element 50 further includes an antiferromagnetic layer 51. The antiferromagnetic layer 51, the magnetization pinned layer 52, the gap layer 53, and the free layer 54 are stacked in this order. The antiferromagnetic layer 51 is formed of an antiferromagnetic material, and is in exchange coupling with the magnetization pinned layer 52 to thereby pin the magnetization direction of the magnetization pinned layer 52. Note that the magnetization pinned layer 52 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled. In a case where the magnetization pinned layer 52 is the self-pinned layer, the antiferromagnetic layer 51 may be omitted.

Note that the layers 51 to 54 of each of the MR elements 50 may be stacked in the reverse order to that shown in FIG. 7.

In FIGS. 3 and 4, solid arrows represent the magnetization directions of the magnetization pinned layers 52 of the MR elements 50. Hollow arrows represent the magnetization directions of the free layers 54 of the MR elements 50 in a case where no target magnetic field is applied to the MR elements 50.

In the example shown in FIG. 3, in each of the resistor sections R11 and R13, the magnetization direction in the magnetization pinned layer 52 is the W1 direction. In each of the resistor sections R12 and R14, the magnetization direction in the magnetization pinned layer 52 is the −W1 direction. The free layer 54 in each of the plurality of first MR elements 50A has a shape anisotropy that sets the direction of the magnetization easy axis to a direction parallel to the U direction. When no target magnetic field is applied to the first MR element 50A, the magnetization direction in the free layer 54 in each of the resistor sections R11 and R12 may be the U direction. In the foregoing case, the magnetization direction in the free layer 54 in each of the resistor sections R13 and R14 may be the −U direction.

In the example shown in FIG. 4, the magnetization direction in the magnetization pinned layer 52 in each of the resistor sections R21 and R23 is the W2 direction. The magnetization direction in the magnetization pinned layer 52 in each of the resistor sections R22 and R24 is the −W2 direction. The free layer 54 in each of the plurality of second MR elements 50B has a shape anisotropy that sets the direction of the magnetization easy axis to a direction parallel to the U direction. When no target magnetic field is applied to the second MR element 50B, the magnetization direction in the free layer 54 in each of the resistor sections R21 and R22 may be the U direction. In the foregoing case, the magnetization direction in the free layer 54 in each of the resistor sections R23 and R24 may be the −U direction.

The magnetic sensor 1 further includes a magnetic field generator configured to apply a magnetic field in a specific direction with respect to the free layer 54 of each of the plurality of first MR elements 50A and the plurality of second MR elements 50B. In the example embodiment, the magnetic field generator includes a coil 70 that applies a magnetic field in a specific direction with respect to the free layer 54 of each of the plurality of first MR elements 50A and the plurality of second MR elements 50B.

Note that the magnetization directions of the magnetization pinned layers 52 and the directions of the magnetization easy axes of the free layers 54 may be slightly deviated from the foregoing directions from the perspective of the accuracy of the manufacturing of the MR elements 50 and the like. The magnetization pinned layers 52 may be magnetized to include magnetization components in the foregoing directions as their main components. In such a case, the magnetization directions of the magnetization pinned layers 52 are the same or substantially the same as the foregoing directions.

In the example embodiment, the MR element 50 is configured so that a current flows in the stacking direction of the plurality of magnetic layers, specifically, the magnetization pinned layer 52 and the free layer 54. As described below, the magnetic sensor 1 includes a lower electrode and an upper electrode for causing a current to flow through the MR element 50. The MR element 50 is arranged between the lower electrode and the upper electrode.

Hereinafter, a specific structure of the magnetic sensor 1 is described in detail with reference to FIGS. 5 and 6. FIG. 6 shows a part of a cross section at a position indicated by the line 6-6 in FIG. 5.

The magnetic sensor 1 includes a substrate 31 including a top surface 31a, insulating layers 32, 33, 34, 35, 36, 37, 38, and 39, a plurality of lower electrodes 61A, a plurality of lower electrodes 61B, a plurality of upper electrodes 62A, a plurality of upper electrodes 62B, a plurality of lower coil elements 71, and a plurality of upper coil elements 72. The top surface 31a of the substrate 31 is parallel to the XY plane. The Z direction is also a direction perpendicular to the top surface 31a of the substrate 31. Note that the coil elements are a part of the coil winding.

The insulating layer 32 is arranged on the substrate 31. The plurality of lower coil elements 71 are arranged on the insulating layer 32. The insulating layer 33 is arranged around the plurality of lower coil elements 71 on the insulating layer 32. The insulating layers 34 and 35 are stacked in this order on the plurality of lower coil elements 71 and the insulating layer 33.

The plurality of lower electrodes 61A and the plurality of lower electrodes 61B are arranged on the insulating layer 35. The insulating layer 36 is arranged in the periphery of the plurality of lower electrodes 61A and the periphery of the plurality of lower electrodes 61B on the insulating layer 35. The plurality of first MR elements 50A are arranged on the plurality of lower electrodes 61A. The plurality of second MR elements 50B are arranged on the plurality of lower electrodes 61B. The insulating layer 37 is arranged in the periphery of the plurality of first MR elements 50A and the periphery of the plurality of second MR elements 50B on the plurality of lower electrodes 61A, the plurality of lower electrodes 61B, and the insulating layer 36. The plurality of upper electrodes 62A are arranged on the plurality of first MR elements 50A and the insulating layer 37. The plurality of upper electrodes 62B are arranged on the plurality of second MR elements 50B and the insulating layer 37. The insulating layer 38 is arranged in the periphery of the plurality of upper electrodes 62A and the periphery of the plurality of upper electrodes 62B on the insulating layer 37.

The insulating layer 39 is arranged on the plurality of upper electrodes 62A, the plurality of upper electrodes 62B, and the insulating layer 38. The plurality of upper coil elements 72 are arranged on the insulating layer 39. The magnetic sensor 1 may further include an insulating layer (omitted in illustration) that covers the plurality of upper coil elements 72 and the insulating layer 39.

Note that, in the description given above, the insulating layers 32 to 39 are distinguished from one another by their arrangement. Some of the insulating layers 32 to 39 may be formed of the same insulating film. Alternatively, at least one insulating layer among the insulating layers 32 to 39 may be formed of a plurality of insulating films.

The magnetic sensor 1 further includes a support member that supports the plurality of first MR elements 50A and the plurality of second MR elements 50B. The support member includes at least one inclined surface inclined with respect to the top surface 31a of the substrate 31. In particular, in the example embodiment, the support member is configured by the insulating layer 35. Note that, in FIG. 5, among the components of the magnetic sensor 1, the insulating layer 35, the plurality of first MR elements 50A, the plurality of second MR elements 50B, and the plurality of upper coil elements 72 are shown.

The insulating layer 35 includes a plurality of protruding surfaces 35 c each protruding in a direction (the Z direction) away from the top surface 31a of the substrate 31. Each of the plurality of protruding surfaces 35c extends in a direction parallel to the U direction. The overall shape of each of the protruding surfaces 35c is a semi-cylindrical curved surface formed by moving the curved shape (arch shape) of the protruding surface 35c shown in FIG. 6 along a direction parallel to the U direction. The plurality of protruding surfaces 35c are arrayed at a specific interval in a direction parallel to the V direction.

Each of the plurality of protruding surfaces 35c includes an upper end portion farthest from the top surface 31a of the substrate 31. In the example embodiment, the upper end portion of each of the plurality of protruding surfaces 35c extends in a direction parallel to the U direction. Herein, focus is placed on a given protruding surface 35c of the plurality of protruding surfaces 35c. The protruding surface 35c includes a first inclined surface 35a and a second inclined surface 35b. The first inclined surface 35a refers to a surface of the protruding surface 35c in the V direction with respect to the upper end portion of the protruding surface 35c. The second inclined surface 35b refers to a surface of the protruding surface 35c in the −V direction with respect to the upper end portion of the protruding surface 35c. In FIG. 5, a boundary between the first inclined surface 35a and the second inclined surface 35b is indicated by a dotted line.

The upper end portion of the protruding surface 35c may be the boundary between the first inclined surface 35a and the second inclined surface 35b. In such a case, the dotted line shown in FIG. 5 indicates the upper end portion of the protruding surface 35c.

The top surface 31a of the substrate 31 is parallel to the XY plane. Each of the first inclined surface 35a and the second inclined surface 35b is inclined with respect to the top surface 31a of the substrate 31, in other words, the XY plane. In a cross section perpendicular to the top surface 31a of the substrate 31, a distance between the first inclined surface 35a and the second inclined surface 35b is smaller in a direction away from the top surface 31a of the substrate 31.

In the example embodiment, the plurality of protruding surfaces 35c are present, and hence the number of each of the first inclined surfaces 35a and the second inclined surfaces 35b is also two or more. The insulating layer 35 includes the plurality of first inclined surfaces 35a and the plurality of second inclined surfaces 35b.

The insulating layer 35 further includes a flat surface 35 d present in the periphery of the plurality of protruding surfaces 35c. The flat surface 35d is a surface parallel to the top surface 31a of the substrate 31. Each of the plurality of protruding surfaces 35c protrudes in the Z direction from the flat surface 35d. In the example embodiment, the plurality of protruding surfaces 35c are arranged at a specific interval. Thus, the flat surface 35d is present between the two protruding surfaces 35c adjacent to each other in the V direction.

The insulating layer 35 includes a plurality of protruding portions each protruding in the Z direction, and a flat portion present in the periphery of the plurality of protruding portions. Each of the plurality of protruding portions extends in a direction parallel to the U direction, and includes the protruding surface 35c. The plurality of protruding portions are arranged at a predetermined interval in a direction parallel to the V direction. The thickness (the dimension in the Z direction) of the flat portion is substantially constant. The insulating layer 34 has a substantially constant thickness (the dimension in the Z direction), and is formed along the bottom surface of the insulating layer 35.

The plurality of lower electrodes 61A are arranged on the plurality of first inclined surfaces 35a. The plurality of lower electrodes 61B are arranged on the plurality of second inclined surfaces 35b. As described above, each of the first inclined surfaces 35a and the second inclined surfaces 35b is inclined with respect to the top surface 31a of the substrate 31, in other words, the XY plane. Thus, the top surface of each of the plurality of lower electrodes 61A and the top surface of each of the plurality of lower electrodes 61B are also inclined with respect to the XY plane. Thus, it can be understood that the plurality of first MR elements 50A and the plurality of second MR elements 50B are arranged on the inclined surfaces inclined with respect to the XY plane. The insulating layer 35 is a member for supporting each of the plurality of first MR elements 50A and the plurality of second MR elements 50B so that the plurality of first MR elements 50A and the plurality of second MR elements 50B are inclined with respect to the XY plane.

Note that, in the example embodiment, the first inclined surface 35 a is a curved surface. Thus, the first MR element 50A is curved along the curved surface (the first inclined surface 35a). In the example embodiment, for the sake of convenience, the magnetization direction in the magnetization pinned layer 52 of the first MR element 50A is defined as a linear direction as described above. The W1 direction and the −W1 direction, which are the magnetization directions in the magnetization pinned layer 52 of the first MR element 50A, are also a direction in which a tangent line contacting a portion of the first inclined surface 35a in the vicinity of the first MR element 50A extends.

Similarly, in the example embodiment, the second inclined surface 35b is a curved surface. Thus, the second MR element 50B is curved along the curved surface (the second inclined surface 35b). In the example embodiment, for the sake of convenience, the magnetization direction in the magnetization pinned layer 52 of the second MR element 50B is defined as a linear direction as described above. The W2 direction and the −W2 direction, which are the magnetization directions in the magnetization pinned layer 52 of the second MR element 50B, are also a direction in which a tangent line contacting a portion of the second inclined surface 35b in the vicinity of the second MR element 50B extends.

As shown in FIG. 5, the plurality of first MR elements 50A are arrayed so that two or more first MR elements 50A are arranged in each of the U direction and the V direction. On one first inclined surface 35a, a plurality of first MR elements 50A are arranged in a single row. Similarly, the plurality of second MR elements 50B are arrayed so that two or more second MR elements 50B are arranged in each of the U direction and the V direction. On one second inclined surface 35b, a plurality of second MR elements 50B are arranged in a single row. In the example embodiment, the row of the plurality of first MR elements 50A and the row of the plurality of second MR elements 50B are alternately arranged in a direction parallel to the V direction.

Note that one first MR element 50A and one second MR element 50B that are adjacent to each other may or may not be deviated from each other in a direction parallel to the U direction as in a plan view in the Z direction. Two first MR elements 50A that are adjacent to each other across one second MR element 50B may or may not be deviated from each other in a direction parallel to the U direction in a plan view in the Z direction. Two second MR elements 50B that are adjacent to each other across one first MR element 50A may or may not be deviated from each other in a direction parallel to the U direction in a plan view in the Z direction.

The plurality of first MR elements 50A are connected in series by the plurality of lower electrodes 61A and the plurality of upper electrodes 62A. Now, with reference to FIG. 7, a method of connecting the plurality of first MR elements 50A is described in detail. In FIG. 7, the reference numeral 61 denotes a lower electrode corresponding to a given MR element 50, and the reference numeral 62 denotes an upper electrode corresponding to the given MR element 50. As shown in FIG. 7, each of the lower electrodes 61 has an elongated shape. A gap is formed between two lower electrodes 61 adjacent to each other in the longitudinal direction of the lower electrode 61. On the top surface of the lower electrode 61, the MR element 50 is arranged in the vicinity of each of one end and the other end in the longitudinal direction. Each of the upper electrodes 62 has an elongated shape, and electrically connects two MR elements 50 that are adjacent to each other and arranged on two lower electrodes 61 adjacent to each other in the longitudinal direction of the lower electrode 61.

Although not shown, one MR element 50 located at the end of a row of a plurality of aligned MR elements 50 is connected to another MR element 50 located at the end of another row of a plurality of MR elements 50 adjacent in a direction intersecting with the longitudinal direction of the lower electrodes 61. Such two MR elements 50 are connected to each other by an electrode (omitted in illustration). The electrode (omitted in illustration) may be an electrode that connects the bottom surfaces or the top surfaces of the two MR elements 50.

When the MR element 50 shown in FIG. 7 is the first MR element 50A, the lower electrode 61 shown in FIG. 7 corresponds to the lower electrode 61A, and the upper electrode 62 shown in FIG. 7 corresponds to the upper electrode 62A. In such a case, the longitudinal direction of the lower electrodes 61 is a direction parallel to the U direction.

Similarly, the plurality of second MR elements 50B are connected in series by the plurality of lower electrodes 61B and the plurality of upper electrodes 62B. The foregoing description of the method of connecting the plurality of first MR elements 50A is also applicable to a method of connecting the plurality of second MR elements 50B. When the MR element 50 shown in FIG. 7 is the second MR element 50B, the lower electrode 61 shown in FIG. 7 corresponds to the lower electrode 61B, and the upper electrode 62 shown in FIG. 7 corresponds to the upper electrode 62B. In such a case, the longitudinal direction of the lower electrodes 61 is a direction parallel to the U direction.

Each of the plurality of upper coil elements 72 extends in a direction parallel to the Y direction. The plurality of upper coil elements 72 are arranged in the X direction. In particular, in the example embodiment, in a plan view in the Z direction, two upper coil elements 72 overlap with each of the plurality of first MR elements 50A and the plurality of second MR elements 50B.

Each of the plurality of lower coil elements 71 extends in a direction parallel to the Y direction. The plurality of lower coil elements 71 are arranged in the X direction. The shape and arrangement of the plurality of lower coil elements 71 may be the same as or different from those of the plurality of upper coil elements 72. In the example shown in FIGS. 5 and 6, the dimension in the X direction of each of the plurality of lower coil elements 71 is smaller than the dimension in the X direction of each of the plurality of upper coil elements 72. The distance between two lower coil elements 71 adjacent to each other in the X direction is smaller than the distance between two upper coil elements 72 adjacent to each other in the X direction.

In the example shown in FIGS. 5 and 6, the plurality of lower coil elements 71 and the plurality of upper coil elements 72 are electrically connected so as to configure the coil 70 that applies a magnetic field in a direction parallel to the X direction with respect to the free layer 54 of each of the plurality of first MR elements 50A and the plurality of second MR elements 50B. For example, the coil 70 may be configured to apply a magnetic field in the X direction with respect to the free layer 54 of each of the resistor sections R11 and R12 of the first detection circuit 10 and the resistor sections R21 and R22 of the second detection circuit 20 and apply a magnetic field in the −X direction with respect to the free layer 54 of each of the resistor sections R13 and R14 of the first detection circuit 10 and the resistor sections R23 and R24 of the second detection circuit 20. The coil 70 may be controlled by the processor 40.

Note that the coil 70 is not an essential component of the magnetic sensor 1, and may not be provided.

Next, the first and second detection signals are described. First, the first detection signal is described with reference to FIG. 3. As the strength of the component of the target magnetic field in a direction parallel to the W1 direction varies, the resistance value of each of the resistor sections R11 to R14 of the first detection circuit 10 varies either so that the resistance values of the resistor sections R11 and R13 are increased and the resistance values of the resistor sections R12 and R14 are reduced or so that the resistance values of the resistor sections R11 and R13 are reduced and the resistance values of the resistor sections R12 and R14 are increased. With this, the electric potential of each of the signal output ends E11 and E12 varies. The first detection circuit 10 generates a signal corresponding to the electric potential of the signal output end E11 as the first detection signal S11, and generates a signal corresponding to the electric potential of the signal output end E12 as the first detection signal S12.

Next, the second detection signal is described with reference to FIG. 4. As the strength of the component of the target magnetic field in a direction parallel to the W2 direction varies, the resistance value of each of the resistor sections R21 to R24 of the second detection circuit 20 varies either so that the resistance values of the resistor sections R21 and R23 are increased and the resistance values of the resistor sections R22 and R24 are reduced or so that the resistance values of the resistor sections R21 and R23 are reduced and the resistance values of the resistor sections R22 and R24 are increased. With this, the electric potential of each of the signal output ends E21 and E22 varies. The second detection circuit 20 generates a signal corresponding to the electric potential of the signal output end E21 as the second detection signal S21, and generates a signal corresponding to the electric potential of the signal output end E22 as the second detection signal S22.

Next, the operation of the processor 40 is described. The processor 40 may be configured to generate the first detection value and the second detection value, based on the first detection signals S11 and S12 and the second detection signals S21 and S22. The first detection value is a detection value corresponding to the component of the target magnetic field in a direction parallel to the V direction. The second detection value is a detection value corresponding to the component of the target magnetic field in a direction parallel to the Z direction. The first detection value is represented by a symbol Sv, and the second detection value is represented by a symbol Sz.

The processor 40 generates the first and second detection values Sv and Sz as follows, for example. First, the processor 40 generates a value S1 by an arithmetic operation that involves obtaining a difference S11−S12 between the first detection signal S11 and the first detection signal S12, and generates a value S2 by an arithmetic operation that involves obtaining a difference S21−S22 between the second detection signal S21 and the second detection signal S22. Next, the processor 40 calculates values S3 and S4 using the following equations (1) and (2).

S3=(S2+S1)/(2 cos α) (1)

S4=(S2−S1)/(2 sin α) (2)

The first detection value Sv may be the value S3 itself, or may be a result of a predetermined correction, such as a gain adjustment or an offset adjustment, made to the value S3. In the same manner, the second detection value Sz may be the value S4 itself, or may be a result of a predetermined correction, such as a gain adjustment or an offset adjustment, made to the value S4.

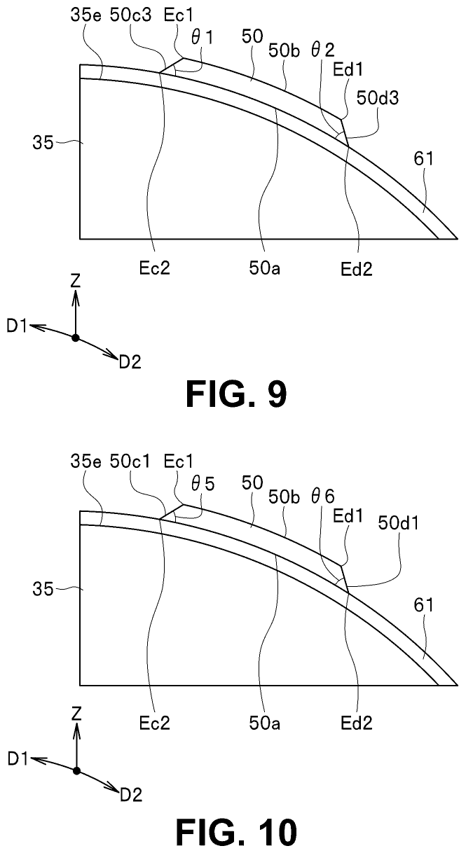

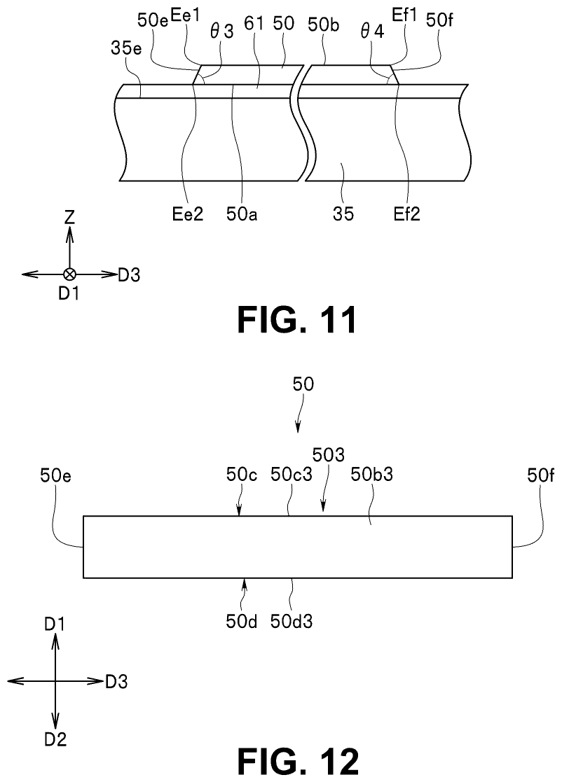

Next, structural features of the magnetic sensor 1 according to the example embodiment are described. First, with reference to FIG. 8, FIG. 9, FIG. 10, and FIG. 11, the shape of the MR element 50 is described in detail. FIG. 8 is a plan view showing a planar shape of the MR element 50. FIG. 9, FIG. 10, and FIG. 11 are cross-sectional views showing a part of the magnetic sensor 1.

FIG. 9 shows a cross section that intersects with the MR element 50 arranged on a given inclined surface 35e and is parallel to a VZ plane. Hereinafter, a cross section parallel to the VZ plane is referred to as a VZ cross section. The VZ cross section shown in FIG. 9 may be the one in which a cross section of the MR element 50 is seen from a position located forward in the U direction as in FIG. 6. In such a case, the MR element 50, the lower electrode 61, and the inclined surface 35e correspond to the first MR element 50A, the lower electrode 61A, and the first inclined surface 35a, respectively. Alternatively, the VZ cross section shown in FIG. 9 may be the one in which a cross section of the MR element 50 is seen from a position located forward in the −U direction. In such a case, the MR element 50, the lower electrode 61, and the inclined surface 35e correspond to the second MR element 50B, the lower electrode 61B, and the second inclined surface 35b, respectively.

The lower electrode 61 is provided between the MR element 50 and the inclined surface 35e. The lower electrode 61 includes a bottom surface facing the inclined surface 35e, a top surface on a side opposite to the bottom surface, and two side surfaces connecting the bottom surface and the top surface (see FIG. 6). Note that the lower electrode 61 may be formed on a region from the inclined surface 35e to the flat surface 35d. In such a case, one of the two side surfaces of the lower electrode 61 is arranged on the inclined surface 35e, and the other is arranged on the flat surface 35d. Alternatively, the entire lower electrode 61 may be arranged on the inclined surface 35e. In such a case, both the two side surfaces of the lower electrode 61 are arranged on the inclined surface 35e.

Herein, as shown in FIG. 8 and FIG. 9, a first direction D1 and a second direction D2 parallel to the VZ plane are defined. The top surface 31a of the substrate 31 (see FIG. 6) serves as a reference plane. The Z direction is one direction perpendicular to the reference plane (the top surface 31a of the substrate 31). The first direction D1 is a direction that extends along the inclined surface 35e and is away from the reference plane (the top surface 31a of the substrate 31). The second direction D2 is a direction that extends along the inclined surface 35e and is closer to the reference plane (the top surface 31a of the substrate 31).

In the following description, a direction that extends along the inclined surface 35e and is parallel to the first direction D1 (a direction parallel to the second direction D2) is simply referred to as a direction along the inclined surface 35e. Such a direction is also a direction that extends along the inclined surface 35e and in which a distance from the reference plane (the top surface 31a of the substrate 31) varies.

As described above, the MR element 50 has a shape anisotropy that sets the direction of the magnetization easy axis to a direction parallel to the U direction. In other words, the MR element 50 has a long shape in a direction parallel to the U direction. As shown in FIG. 8, the longitudinal direction of the MR element 50 (a direction parallel to the U direction) is also referred to as a third direction D3. The VZ cross section is orthogonal to the longitudinal direction of the MR element 50. The “direction along the inclined surface 35e” defined as above is also the short direction of the MR element 50.

The MR element 50 includes a bottom surface 50 a facing the inclined surface 35e, a top surface 50b on a side opposite to the bottom surface 50a, a first end portion 50c located at one end of the MR element 50 in the short direction (the direction along the inclined surface 35e), and a second end portion 50d located at the other end thereof. The first end portion 50c includes an end of the MR element 50 in the first direction D1. The second end portion 50d includes an end of the MR element 50 in the second direction D2.

Each of the first end portion 50 c and the second end portion 50 d is a surface that connects the bottom surface 50a and the top surface 50b. The surface may be a flat surface, a curved surface, or a surface including a flat surface and a curved surface.

Each of the first end portion 50c and the second end portion 50d is inclined with respect to a direction perpendicular to the inclined surface 35e. As shown in FIGS. 9 and 10, a lower end Ec2 of the first end portion 50c is located at a position forward of an upper end Ec1 of the first end portion 50c in the first direction D1. A lower end Ed2 of the second end portion 50d is located at a position forward of an upper end Ed1 of the second end portion 50d in the second direction D2.

The MR element 50 further includes a third end portion 50e located at one end of the MR element 50 in the longitudinal direction (the third direction D3), and a fourth end portion 50f located at the other end thereof. The third end portion 50e includes an end of the MR element 50 in one direction parallel to the third direction D3. The fourth end portion 50f includes an end of the MR element 50 in the other direction parallel to the third direction D3.

Each of the third end portion 50e and the fourth end portion 50f is inclined with respect to a direction perpendicular to the inclined surface 35e. As shown in FIG. 11, a lower end Ee2 of the third end portion 50e is located at a position forward of an upper end Ee1 of the third end portion 50e in one direction parallel to the third direction D3. A lower end Ef2 of the fourth end portion 50f is located at a position forward of an upper end Ef1 of the fourth end portion 50f in the other direction parallel to the third direction D3.

Each of the third end portion 50e and the fourth end portion 50f may be an edge formed by the first end portion 50c and the second end portion 50d intersecting with each other. Note that the shape of the edge may be either pointed or rounded.

The MR elements 50 each include a first non-constant portion 501 and a second non-constant portion 502 where an interval between the first end portion 50c and the second end portion 50d is reduced along the longitudinal direction of the MR element 50 (the third direction D3), and a constant portion 503 where an interval between the first end portion 50c and the second end portion 50d is constant regardless of a position in the longitudinal direction of the MR element 50 (the third direction D3). The constant portion 503 is arranged between the first non-constant portion 501 and the second non-constant portion 502. In other words, the second non-constant portion 502 is arranged so that the constant portion 503 is interposed between the first non-constant portion 501 and the second non-constant portion 502. In FIG. 8, each of a boundary between the first non-constant portion 501 and the constant portion 503 and a boundary between the second non-constant portion 502 and the constant portion 503 is indicated by a dotted line. The first non-constant portion 501, the constant portion 503, and the second non-constant portion 502 are arrayed in this order along the third direction D3.

The first non-constant portion 501 includes a top surface portion 50b1, which is a part of the top surface 50b. The second non-constant portion 502 includes a top surface portion 50b2, which is another part of the top surface 50b. The constant portion 503 includes a top surface portion 50b3, which is a further another part of the top surface 50b.

The second non-constant portion 502 may have a shape symmetric to the first non-constant portion 501 with respect to a virtual plane that intersects with the MR element 50 and intersects with the third direction D3.

The first end portion 50 c includes a side surface 50c1 included in the first non-constant portion 501, a side surface 50c2 included in the second non-constant portion 502, and a side surface 50c3 included in the constant portion 503. The side surface 50c3 connects the side surface 50c1 and the side surface 50c2. The second end portion 50d includes a side surface 50d1 included in the first non-constant portion 501, a side surface 50d2 included in the second non-constant portion 502, and a side surface 50d3 included in the constant portion 503. The side surface 50d3 connects the side surface 50d1 and the side surface 50d2.

At least a part of each of the side surfaces 50c1, 50c2, and 50c3 of the first end portion 50c and the side surfaces 50d1, 50d2, and 50d3 of the second end portion 50d has a linear shape. Note that, in the disclosure, the “linear shape” includes a case of an actual linear line and a case where the shape can be regarded to extend along a virtual linear line in a plan view in the Z direction. In particular, the side surfaces 50c1, 50c2, 50d1, and 50d2 extend along virtual linear lines Lc1, Lc2, Ld1, and Ld2, respectively. Each of the virtual linear lines Lc1, Lc2, Ld1, and Ld2 is inclined with respect to each of the third direction D3 and the top surface 31a of the substrate 31. Technically, when the inclined surface 35e is curved, each of the side surfaces 50c1, 50c2, 50d1, and 50d2 is also curved.

An edge may be formed between the side surface 50c1 and the side surface 50c3, between the side surface 50c2 and the side surface 50c3, between the side surface 50d1 and the side surface 50d3, and between the side surface 50d2 and the side surface 50d3. Note that the shape of the edge may be either pointed or rounded.

Next, features relating to an angle formed by each of the first end portion 50c, the second end portion 50d, the third end portion 50e, and the fourth end portion 50f with respect to the bottom surface 50a of the MR element 50 are described. FIG. 9 shows a cross section that is parallel to the VZ cross section and intersects with each of the side surface 50c3 of the first end portion 50c and the side surface 50d3 of the second end portion 50d. The cross section shown in FIG. 9 corresponds to the “first cross section” in the disclosure.

Here, as shown in FIG. 9, an angle formed by the side surface 50c3 with respect to the bottom surface 50a of the MR element 50 in the VZ cross section is a first angle θ1, and an angle formed by the side surface 50d3 with respect to the bottom surface 50a of the MR element 50 in the VZ cross section is a second angle θ2.

When the first angle θ1 is 90 degrees, the side surface 50c3 is perpendicular to the bottom surface 50a, and is substantially perpendicular to the inclined surface 35e. The first angle θ1 may be greater than 0 degrees and smaller than 90 degrees. When an interval between the bottom surface 50a and the top surface 50b in a direction perpendicular to the inclined surface 35e is constant, as the first angle θ1 approaches 90 degrees from 0 degrees, inclination of the side surface 50c3 with respect to the bottom surface 50a is increased, and the dimension of the side surface 50c3 in a direction along the inclined surface 35e is reduced. Reduction in dimension of the side surface 50c3 in a direction along the inclined surface 35e can be understood as a reduction in taper of the side surface 50c3. Note that, in the following description, inclination of a given side surface with respect to the bottom surface 50a is simply referred to as inclination.

The foregoing description relating to the first angle θ1 and the side surface 50c3 is also applicable to the second angle θ2 and the side surface 50d3. The foregoing description relating to the first angle θ1 and the side surface 50c3 is also applicable to the angles and the side surfaces used in the following description.

FIG. 11 shows a cross section that intersects with the MR element 50 arranged on a given inclined surface 35e and intersects with the short direction of the MR element 50 (a direction along the inclined surface 35e). In particular, FIG. 11 shows a cross section intersecting with each of the third end portion 50e and the fourth end portion 50f of the MR element 50. The cross section shown in FIG. 11 corresponds to the “second cross section” in the disclosure. Note that the “second cross section” may be a cross section orthogonal to the short direction of the MR element 50, or may be a cross section parallel to the UZ plane (a cross section orthogonal to the top surface 31a of the substrate 31). FIG. 11 shows an example in which the “second cross section” is a cross section orthogonal to the short direction of the MR element 50.

Here, in the cross section shown in FIG. 11, an angle formed by the third end portion 50e with respect to the bottom surface 50a of the MR element 50 is a third angle θ3, and an angle formed by the fourth end portion 50f with respect to the bottom surface 50a of the MR element 50 is a fourth angle θ4.

FIG. 10 shows a cross section that is parallel to the VZ cross section (the first cross section) shown in FIG. 9 and intersects with each of the side surface 50c1 of the first end portion 50c and the side surface 50d1 of the second end portion 50d. FIG. 10 corresponds to the “third cross section” in the disclosure.

Here, as shown in FIG. 10, an angle formed by the side surface 50c1 with respect to the bottom surface 50a of the MR element 50 in the VZ cross section is a fifth angle θ5, and an angle formed by the side surface 50d1 with respect to the bottom surface 50a of the MR element 50 in the VZ cross section is a sixth angle θ6.

In the example embodiment, at least one of the first angle θ1 and the second angle θ2 is equal to or smaller than the third angle θ3. In other words, inclination of at least one of the side surface 50c3 of the first end portion 50c and the side surface 50d3 of the second end portion 50d is smaller than inclination of the third end portion 50e. In other words, inclination of the third end portion 50e is larger than inclination of at least one of the side surface 50c3 of the first end portion 50c and the side surface 50d3 of the second end portion 50d. Note that both the first angle θ1 and the second angle θ2 may be equal to or smaller than the third angle θ3.

At least two of the first angle θ1, the second angle θ2, and the third angle θ3 may be different from each other. For example, the first angle θ1, the second angle θ2, and the third angle θ3 may be different from one another.

At least one of the first angle θ1 and the second angle θ2 may be equal to or smaller than the fourth angle θ4. In other words, inclination of at least one of the side surface 50c3 of the first end portion 50c and the side surface 50d3 of the second end portion 50d is smaller than inclination of the fourth end portion 50f. In other words, inclination of the fourth end portion 50f is larger than inclination of at least one of the side surface 50c3 of the first end portion 50c and the side surface 50d3 of the second end portion 50d. Note that both the first angle θ1 and the second angle θ2 may be equal to or smaller than the fourth angle θ4.

At least two of the first angle θ1, the second angle θ2, and the fourth angle θ4 may be different from each other. For example, the first angle θ1, the second angle θ2, and the fourth angle θ4 may be different from one another.

The third angle θ3 and the fourth angle θ4 may be equal or substantially equal to each other. In other words, the third end portion 50e and the fourth end portion 50f may have the same or substantially same inclination. Now, a difference between the third angle θ3 and the fourth angle θ4 is described, taking the third angle θ3 as a reference. The difference between the third angle θ3 and the fourth angle θ4 may be less than each of a first value and a second value, the first value being obtained by subtracting the first angle θ1 from the third angle θ3, the second value being obtained by subtracting the second angle θ2 from the third angle θ3. Note that the difference between the two angles may be expressed as an absolute value.

The first angle θ1 and the second angle θ2 may be equal or substantially equal to each other, or may be different from each other. When the first angle θ1 and the second angle θ2 are equal or substantially equal to each other, inclination of the side surface 50c3 of the first end portion 50c and inclination of the side surface 50d3 of the second end portion 50d are equal or substantially equal to each other. In such a case, a third value, which is obtained by subtracting the first angle θ1 from the second angle θ2,may be less than each of the first value, which is obtained by subtracting the first angle θ1 from the third angle θ3, and the second value, which is obtained by subtracting the second angle θ2 from the third angle θ3.

When the first angle θ1 is larger than the second angle θ2, inclination of the side surface 50c3 of the first end portion 50c is larger than inclination of the side surface 50d3 of the second end portion 50d. Now, a difference between the first angle θ1 and the second angle θ2 is described, taking the third angle θ3 as a reference. In such a case, the first value, which is obtained by subtracting the first angle θ1 from the third angle θ3, is less than the second value, which is obtained by subtracting the second angle θ2 from the third angle θ3.

When the first angle θ1 is smaller than the second angle θ2, inclination of the side surface 50c3 of the first end portion 50c is smaller than inclination of the side surface 50d3 of the second end portion 50d. Now, a difference between the first angle θ1 and the second angle θ2 is described, taking the third angle θ3 as a reference. In such a case, the first value, which is obtained by subtracting the first angle θ1 from the third angle θ3, is greater than the second value, which is obtained by subtracting the second angle θ2 from the third angle θ3.

Each of the fifth angle θ5 and the sixth angle θ6 may be equal to or smaller than the third angle θ3. In other words, each of inclination of the side surface 50c1 of the first end portion 50c and inclination of the side surface 50d1 of the second end portion 50d is equal to or smaller than inclination of the third end portion 50e. In other words, inclination of the third end portion 50e is equal to each of inclination of the side surface 50c1 of the first end portion 50c and inclination of the side surface 50d1 of the second end portion 50d, or is larger than each of inclination of the side surface 50c1 of the first end portion 50c and inclination of the side surface 50d1 of the second end portion 50d.

Each of the fifth angle θ5 and the sixth angle θ6 may be equal to or smaller than the fourth angle θ4. In other words, each of inclination of the side surface 50c1 of the first end portion 50c and inclination of the side surface 50d1 of the second end portion 50d is equal to or smaller than inclination of the fourth end portion 50f. In other words, inclination of the fourth end portion 50f is equal to each of inclination of the side surface 50c1 of the first end portion 50c and inclination of the side surface 50d1 of the second end portion 50d, or is larger than each of inclination of the side surface 50c1 of the first end portion 50c and inclination of the side surface 50d1 of the second end portion 50d.

The first angle θ1 and the fifth angle θ5 may be equal or substantially equal to each other, or may be different from each other. In other words, inclination of the side surface 50c1 of the first end portion 50c may be equal to or substantially equal to inclination of the side surface 50c3 of the first end portion 50c, or may be different from inclination of the side surface 50c3 of the first end portion 50c.

The second angle θ2 and the sixth angle θ6 may be equal or substantially equal to each other, or may be different from each other. In other words, inclination of the side surface 50d1 of the second end portion 50d may be equal to or substantially equal to inclination of the side surface 50d3 of the second end portion 50d, or may be different from inclination of the side surface 50d3 of the second end portion 50d.

Here, an angle formed by the side surface 50c2 with respect to the bottom surface 50a of the MR element 50 in a cross section intersecting with each of the side surface 50c2 of the first end portion 50c and the side surface 50d2 of the second end portion 50d is a seventh angle, and an angle formed by the side surface 50d2 with respect to the bottom surface 50a of the MR element 50 in such a cross section is an eighth angle. The foregoing description relating to the fifth angle θ5 and the sixth angle θ6 is also applicable to the seventh angle and the eighth angle.

Next, a method of manufacturing the magnetic sensor 1 in the example embodiment is briefly described. The steps of manufacturing the magnetic sensor 1 include a step of forming the insulating layer 35 as a support member, and a step of forming the plurality of MR elements 50. The insulating layer 35 is formed by forming an insulating film made of an insulating material by chemical vapor deposition or physical vapor deposition, and then subjecting the insulating film to patterning so that the plurality of protruding surfaces 35c are formed on the insulating film. The plurality of MR elements 50 are formed on the insulating layer 35.

In the step of forming the plurality of MR elements 50, first, a stack film, which later serves as the plurality of MR elements 50, is formed. The stack film includes an initial magnetization pinned layer, which later serves as the magnetization pinned layer 52, the antiferromagnetic layer 51, the gap layer 53, and the free layer 54. Subsequently, on the stack film, a mask material layer is formed. Then, the mask material layer is subjected to patterning by using, for example, photolithography, thereby forming a plurality of masks. Each of the plurality of masks has a shape in conformity with the planar shape of the MR element 50.

Subsequently, the stack film is subjected to patterning by, for example, ion beam etching using a plurality of masks. In this manner, a plurality of initial MR elements are formed. Each of the plurality of initial MR elements includes the initial magnetization pinned layer, the antiferromagnetic layer 51, the gap layer 53, and the free layer 54. Subsequently, the magnetization direction of the initial magnetization pinned layer is fixed by using an external magnetic field. In this manner, the initial magnetization pinned layer serves as the magnetization pinned layer, and the plurality of initial MR elements serve as the plurality of MR elements 50.

Note that the step of fixing the magnetization direction of the initial magnetization pinned layer may be performed before the step of subjecting the stack film to patterning.

Next, operations and effects of the magnetic sensor 1 according to the example embodiment are described. In the vicinity of each of the first end portion 50c, the second end portion 50d, and the third end portion 50e, a shape demagnetizing field in a direction opposite to an external magnetic field is generated due to the respective shapes of the first end portion 50c, the second end portion 50d, and the third end portion 50e. When each of inclination of the first end portion 50c and inclination of the second end portion 50d is larger than inclination of the third end portion 50e, a shape demagnetizing field in the vicinity of each of the first end portion 50c and the second end portion 50d is relatively larger than that in the vicinity of the third end portion 50e. As a result, the magnetization of the free layer 54 is less likely to be oriented in the short direction of the MR element 50, and sensitivity of the MR element 50 is degraded. In this manner, depending on a magnitude of the angle formed by each end portion of the MR element 50 with respect to the inclined surface 35e, sensitivity of the MR element 50 may be affected.

In contrast, in the example embodiment, inclination of at least one of the first end portion 50c and the second end portion 50d is smaller than inclination of the third end portion 50e. Specifically, at least one of the first angle θ1 and the second angle θ2 is equal to or smaller than the third angle θ3. With this, according to the example embodiment, degradation of sensitivity of the MR element 50 can be suppressed. Each of inclination of the first end portion 50c and inclination of the second end portion 50d is smaller than inclination of the third end portion 50e. With this, degradation of sensitivity of the MR element 50 can be suppressed more effectively.

The foregoing description relating to the group including the first end portion 50c, the second end portion 50d, and the third end portion 50e is also applicable to the group including the first end portion 50c, the second end portion 50d, and the fourth end portion 50f.

Note that, when each of inclination of the first end portion 50c and inclination of the second end portion 50d is reduced excessively, a shape demagnetizing field in the vicinity of each of the first end portion 50c and the second end portion 50d is reduced, and the magnetization of the free layer 54 tends to be oriented in the short direction of the MR element 50. As a result, hysteresis of the magnetization of the free layer 54 is increased, and the hysteresis characteristics of the MR element 50 are degraded. Thus, depending on the magnitude of the angle formed by each end portion of the MR element 50 with respect to the inclined surface 35e, the hysteresis characteristics of the MR element 50 may be affected. Thus, within a range in which each of inclination of the first end portion 50c and inclination of the second end portion 50d is not reduced excessively, inclination of at least one of the first end portion 50c and the second end portion 50d may be smaller than that of the third end portion 50e. With this, according to the example embodiment, degradation of the hysteresis characteristics and sensitivity of the MR element 50 can be respectively suppressed.

### Modification Examples

Next, first and second modification examples of the MR element 50 are described. First, with reference to FIG. 12, the first modification example of the MR element 50 is described. FIG. 12 is a plan view showing the first modification example of the MR element 50. In the first modification example, the MR element 50 includes the constant portion 503, but does not include the first and second non-constant portions 501 and 502. The planar shape of the MR element 50 may be a rectangular shape that is elongated in one direction and has a constant width or a substantially constant width regardless of a position in the longitudinal direction of the MR element 50 (the third direction D3).

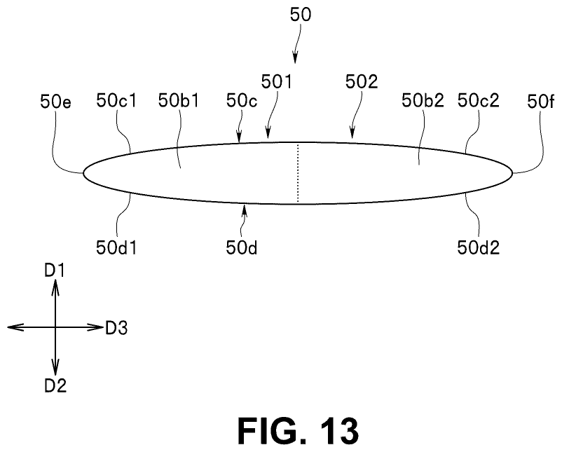

Next, with reference to FIG. 13, the second modification example of the MR element 50 is described. FIG. 13 is a plan view showing the second modification example of the MR element 50. In the second modification example, the MR element 50 includes the first and second non-constant portions 501 and 502, but does not include the constant portion 503. In the example shown in FIG. 13, the planar shape of the MR element 50 is an elliptical shape. In FIG. 13, a boundary between the first non-constant portion 501 and the second non-constant portion 502 is indicated by a dotted line. The dimension of the MR element 50 in a direction along the inclined surface 35e may reach its maximum at the boundary between the first non-constant portion 501 and the second non-constant portion 502.

Note that the disclosure is not limited to the foregoing embodiments, and various modifications may be made. For example, the planar shape of the MR element 50 is not limited to the examples given in the example embodiment.

Each of the first inclined surfaces 35a and the second inclined surfaces 35b may include a flat portion. Alternatively, the overall shape of the protruding surface 35c may be a triangular roof-like shape.

The insulating layer 35 may include a plurality of groove portions recessed in the −Z direction from the top surface of the insulating layer 35, instead of the plurality of protruding portions. The plurality of groove portions may be arranged at a specific interval in a direction parallel to the V direction. Each of the plurality of groove portions may include a first inclined surface and a second inclined surface. The first inclined surface is a surface of the groove portion in the −V direction with respect to a lower end portion of the groove portion. The second inclined surface is a surface of the groove portion in the V direction with respect to the lower end portion of the groove portion. Each of the plurality of MR elements 50 is arranged on the first inclined surface or the second inclined surface.

The magnetic detection element of the disclosure is not limited to the MR element 50, and may be an element that includes a magnetic film where a shape demagnetizing field is generated.

As described above, a magnetic sensor according to one embodiment of the disclosure includes a reference plane, a support member that is arranged on the substrate, and includes an inclined surface inclined with respect to the reference plane, and a magnetic detection element that is arranged on the inclined surface, and has a long shape in one direction. The magnetic detection element includes a bottom surface facing the inclined surface, a top surface on a side opposite to the bottom surface, a first end portion located at one end of the magnetic detection element in a short direction, a second end portion located at the other end of the magnetic detection element in the short direction, a third end portion located at one end of the magnetic detection element in a longitudinal direction, and a fourth end portion located at the other end of the magnetic detection element in the longitudinal direction. The first end portion is inclined at a first angle with respect to the bottom surface in a first cross section perpendicular to the longitudinal direction. The second end portion is inclined at a second angle with respect to the bottom surface in the first cross section. The third end portion is inclined at a third angle with respect to the bottom surface in a second cross section intersecting with the short direction. At least one of the first angle and the second angle is equal to or smaller than the third angle.

In the magnetic sensor of the disclosure, the fourth end portion may be inclined at a fourth angle with respect to the bottom surface in the second cross section. At least one of the first angle and the second angle may be equal to or smaller than the fourth angle. A difference between the third angle and the fourth angle may be less than each of a first value and a second value, the first value being obtained by subtracting the first angle from the third angle, the second value being obtained by subtracting the second angle from the third angle.

In the magnetic sensor according to the embodiment of the disclosure, the first end portion may be at a position located farther from the substrate than the second end portion. A first value, which is obtained by subtracting the first angle from the third angle, may be greater than a second value, which is obtained by subtracting the second angle from the third angle.

In the magnetic sensor according to the embodiment of the disclosure, the first end portion may be at a position located farther from the substrate than the second end portion. A second value, which is obtained by subtracting the second angle from the third angle, may be greater than a first value, which is obtained by subtracting the first angle from the third angle.

In the magnetic sensor according to the embodiment of the disclosure, a third value, which is obtained by subtracting the first angle from the second angle, may be less than each of a first value, which is obtained by subtracting the first angle from the third angle, and a second value, which is obtained by subtracting the second angle from the third angle.

In the magnetic sensor according to the embodiment of the disclosure, the magnetic detection element may include a first non-constant portion where an interval between the first end portion and the second end portion is reduced along the longitudinal direction.

In the magnetic sensor according to the embodiment of the disclosure, the magnetic detection element may further include a constant portion where an interval between the first end portion and the second end portion is substantially constant in the longitudinal direction.

In the magnetic sensor according to the embodiment of the disclosure, the magnetic detection element may further include a second non-constant portion where an interval between the first end portion and the second end portion is reduced along the longitudinal direction, the second non-constant portion being arranged at a position at which the constant portion is interposed between the first non-constant portion and the second non-constant portion.

In the magnetic sensor according to the embodiment of the disclosure, the first end portion may include a first side surface included in the constant portion and a second side surface included in the first non-constant portion. The second end portion may include a third side surface included in the constant portion and a fourth side surface included in the first non-constant portion. The first angle may be an angle formed by the first side surface with respect to the bottom surface in the first cross section. The second angle may be an angle formed by the third side surface with respect to the bottom surface in the first cross section. The second side surface may be inclined at a fifth angle with respect to the bottom surface in a third cross section parallel to the first cross section. The fourth side surface may be inclined at a sixth angle with respect to the bottom surface in the third cross section. Each of the fifth angle and the sixth angle may be equal to or smaller than the third angle. The first angle and the fifth angle may be different from each other. The second angle and the sixth angle may be different from each other.

The technology according to the present disclosure can also be expressed, for example, as configurations shown in the following clauses. The technology according to the present disclosure is not limited to these configurations.

Clause 1. A magnetic sensor including:
a substrate that includes a reference plane; a support member that is arranged on the substrate, and includes an inclined surface inclined with respect to the reference plane; and a magnetic detection element that is arranged on the inclined surface, and has a long shape in one direction, in which the magnetic detection element includes: a bottom surface facing the inclined surface; a top surface on a side opposite to the bottom surface; a first end portion located at one end of the magnetic detection element in a short direction; a second end portion located at the other end of the magnetic detection element in the short direction; a third end portion located at one end of the magnetic detection element in a longitudinal direction; and a fourth end portion located at the other end of the magnetic detection element in the longitudinal direction, the first end portion is inclined at a first angle with respect to the bottom surface in a first cross section perpendicular to the longitudinal direction, the second end portion is inclined at a second angle with respect to the bottom surface in the first cross section, the third end portion is inclined at a third angle with respect to the bottom surface in a second cross section intersecting with the short direction, and at least one of the first angle and the second angle is equal to or smaller than the third angle.

Clause 2. The magnetic sensor according to clause 1, in which:
the fourth end portion is inclined at a fourth angle with respect to the bottom surface in the second cross section; and
at least one of the first angle and the second angle is equal to or smaller than the fourth angle.

Clause 3. The magnetic sensor according to clause 2, in which a difference between the third angle and the fourth angle is less than each of a first value and a second value, the first value being obtained by subtracting the first angle from the third angle, the second value being obtained by subtracting the second angle from the third angle.

Clause 4. The magnetic sensor according to any of clauses 1 to 3, in which:
the first end portion is at a position located farther from the substrate than the second end portion; and
when a value obtained by subtracting the first angle from the third angle is a first value, and a value obtained by subtracting the second angle from the third angle is a second value, the first value is greater than the second value.

Clause 5. The magnetic sensor according to any of clauses 1 to 3, in which:
the first end portion is at a position located farther from the substrate than the second end portion; and
when a value obtained by subtracting the first angle from the third angle is a first value, and a value obtained by subtracting the second angle from the third angle is a second value, the second value is greater than the first value.

Clause 6. The magnetic sensor according to any of clauses 1 to 5, in which, when a value obtained by subtracting the first angle from the third angle is a first value, a value obtained by subtracting the second angle from the third angle is a second value, and a value obtained by subtracting the first angle from the second angle is a third value, the third value is less than each of the first value and the second value.

Clause 7. The magnetic sensor according to any of clauses 1 to 6, in which the magnetic detection element includes a first non-constant portion where an interval between the first end portion and the second end portion is reduced along the longitudinal direction.

Clause 8. The magnetic sensor according to clause 7, in which the magnetic detection element further includes a constant portion where an interval between the first end portion and the second end portion is constant regardless of a position in the longitudinal direction.

Clause 9. The magnetic sensor according to clause 8, in which the magnetic detection element further includes a second non-constant portion where an interval between the first end portion and the second end portion is reduced along the longitudinal direction, the second non-constant portion being arranged at a position at which the constant portion is interposed between the first non-constant portion and the second non-constant portion.

Clause 10. The magnetic sensor according to clause 8 or 9, in which:
the first end portion includes a first side surface included in the constant portion and a second side surface included in the first non-constant portion;
the second end portion includes a third side surface included in the constant portion and a fourth side surface included in the first non-constant portion;
the first angle is an angle formed by the first side surface with respect to the bottom surface in the first cross section;
the second angle is an angle formed by the third side surface with respect to the bottom surface in the first cross section;
the second side surface is inclined at a fifth angle with respect to the bottom surface in a third cross section parallel to the first cross section;
the fourth side surface is inclined at a sixth angle with respect to the bottom surface in the third cross section; and
each of the fifth angle and the sixth angle is equal to or smaller than the third angle.

Clause 11. The magnetic sensor according to clause 10, in which:
the first angle and the fifth angle are different from each other; and
the second angle and the sixth angle are different from each other.

In the disclosure, at least one of the first angle and the second angle is equal to or smaller than the third angle. With this, the magnetic sensor of the disclosure can achieve desired characteristics.

It is apparent that the disclosure can be carried out in various forms and modifications in the light of the foregoing descriptions. Accordingly, within the scope of the following claims and equivalents thereof, the disclosure can be carried out in forms other than the foregoing example embodiments.

1. A magnetic sensor comprising:
a substrate that includes a reference plane;
a support member that is arranged on the substrate, and includes an inclined surface inclined with respect to the reference plane; and
a magnetic detection element that is arranged on the inclined surface, and has a long shape in one direction, wherein
the magnetic detection element includes:
a bottom surface facing the inclined surface;
a top surface on a side opposite to the bottom surface;
a first end portion located at one end of the magnetic detection element in a short direction;
a second end portion located at the other end of the magnetic detection element in the short direction;
a third end portion located at one end of the magnetic detection element in a longitudinal direction; and
a fourth end portion located at the other end of the magnetic detection element in the longitudinal direction,
the first end portion is inclined at a first angle with respect to the bottom surface in a first cross section perpendicular to the longitudinal direction,
the second end portion is inclined at a second angle with respect to the bottom surface in the first cross section,
the third end portion is inclined at a third angle with respect to the bottom surface in a second cross section intersecting with the short direction, and
at least one of the first angle and the second angle is equal to or smaller than the third angle.

2. The magnetic sensor according to claim 1, wherein:
the fourth end portion is inclined at a fourth angle with respect to the bottom surface in the second cross section; and
at least one of the first angle and the second angle is equal to or smaller than the fourth angle.

3. The magnetic sensor according to claim 2, wherein a difference between the third angle and the fourth angle is less than each of a first value and a second value, the first value being obtained by subtracting the first angle from the third angle, the second value being obtained by subtracting the second angle from the third angle.

4. The magnetic sensor according to claim 1, wherein:
the first end portion is at a position located farther from the substrate than the second end portion; and
a first value, which is obtained by subtracting the first angle from the third angle, is greater than a second value, which is obtained by subtracting the second angle from the third angle.

5. The magnetic sensor according to claim 1, wherein:
the first end portion is at a position located farther from the substrate than the second end portion; and
a second value, which is obtained by subtracting the second angle from the third angle, is greater than a first value, which is obtained by subtracting the first angle from the third angle.

6. The magnetic sensor according to claim 1, wherein a third value, which is obtained by subtracting the first angle from the second angle, is less than each of a first value, which is obtained by subtracting the first angle from the third angle, and a second value, which is obtained by subtracting the second angle from the third angle.

7. The magnetic sensor according to claim 1, wherein the magnetic detection element includes a first non-constant portion where an interval between the first end portion and the second end portion is reduced along the longitudinal direction.

8. The magnetic sensor according to claim 7, wherein the magnetic detection element further includes a constant portion where an interval between the first end portion and the second end portion is substantially constant in the longitudinal direction.

9. The magnetic sensor according to claim 8, wherein the magnetic detection element further includes a second non-constant portion where an interval between the first end portion and the second end portion is reduced along the longitudinal direction, the second non-constant portion being arranged at a position at which the constant portion is interposed between the first non-constant portion and the second non-constant portion.

10. The magnetic sensor according to claim 8, wherein:
the first end portion includes a first side surface included in the constant portion and a second side surface included in the first non-constant portion;
the second end portion includes a third side surface included in the constant portion and a fourth side surface included in the first non-constant portion; the first angle is an angle formed by the first side surface with respect to the bottom surface in the first cross section; the second angle is an angle formed by the third side surface with respect to the bottom surface in the first cross section; the second side surface is inclined at a fifth angle with respect to the bottom surface in a third cross section parallel to the first cross section; the fourth side surface is inclined at a sixth angle with respect to the bottom surface in the third cross section; and each of the fifth angle and the sixth angle is equal to or smaller than the third angle.

11. The magnetic sensor according to claim 10, wherein:
the first angle and the fifth angle are different from each other; and
the second angle and the sixth angle are different from each other.
